(19) United States
(12) Patent Application Publication
(10) Pub. No.: US 2011/0307757 A1
(43) Pub. Date: Dec. 15, 2011

(54) SYSTEMS AND METHODS FOR ERROR CORRECTION

(75) Inventor: Marius Petru Bonaciu, Natick, MA (US)

(73) Assignee: MIRICS, Semiconductor Limited, Fleet (GB)

(21) Appl. No.: 12/814,099

(22) Filed: Jun. 11, 2010

(51) Int. Cl. H03M 13/05; H03M 13/07; G06F 11/10

(52) U.S. Cl. 714/758; 714/759; 714/784; 714/E11.032

(57) ABSTRACT

Systems, methods, and an article of manufacture for decoding a broadcast signal are shown and described. In particular, aspects of the Reed-Solomon decoding algorithm are improved to thereby reduce the amount of processing time required to execute the Reed-Solomon decoding.

### TECHNICAL FIELD

The present subject matter relates to techniques and equipment for communications systems. In more detail, it relates to techniques and equipment for decoding broadcast signals.

### BACKGROUND

Serial concatenated decoding typically involves two decoders connected in series. The first decoder is typically called the inner decoder and the second decoder is called the outer decoder. Serial concatenated decoding lends itself to many uses. One example is recovering information bits from a code word.

In a more specific example, the digital video broadcast terrestrial standard uses serial concatenated encoding at the transmitter. The transmitter includes a non-binary block code (e.g., a Reed-Solomon (RS) code) followed by a punctured convolution code (often referred to as forward error correction). In order to view the broadcast, the receiver uses serial concatenated decoding. A typical implementation uses a Viterbi decoder as the inner decoder and a Reed-Solomon decoder as the outer decoder.

The Reed-Solomon relies on the fact that for each packet of transmitted data, a small amount of additional data (i.e., parity bits) are attached. That additional information can be used to correct possible errors caused by the data transmission. The algorithm consists of two important phases: (1) error detection, which detects if there are errors present into the current data package; and (2) error correction, which corrects the errors when they are detected using the error detection phase.

The Reed-Solomon algorithm basically consists of a large amount of exclusive-or based operations, using Galois-Fields polynomial coefficients. Thus, the algorithm is very highly mathematical intensive. In some decoding applications, the Reed-Solomon algorithm counts for as much as ten percent of the entire processing time, even for an error free signal, even after using existing hardware instruction optimizations.

### SUMMARY

In one example, the present disclosure is directed to a system, method, and article of manufacture for decoding a received broadcast signal. In particular, aspects of the Reed-Solomon decoding algorithm are improved to thereby reduce the amount of processing time required to execute the Reed-Solomon decoding.

In one aspect, a method of decoding a received broadcast signal is shown and described. The method includes computing for each input of an error detection algorithm, prior to decoding the broadcast signal, a set of possible outcomes of the error detection algorithm and storing in a first look-up table, the computed set of possible outcomes of the error detection algorithm. The method also includes computing for each input of an error correction algorithm, prior to decoding the broadcast signal, a set of possible error correction outcomes and storing in a second look-up table the computed set of possible error correction outcomes. Also, the method includes detecting an error in a received broadcast signal using the first look-up table and correcting the error using the second look-up table when an error is detected.

In various examples, the detecting occurs using only the first look-up table and the correcting occurs using only the second look-up table. The look-up tables can be stored as three dimensional arrays. The error correction and error detection algorithm can be a Reed-Solomon algorithm. The error correction algorithm can include performing a Chien search. The broadcast signal can be a digital radio signal, a digital television broadcast signal, or some other broadcast signal. Additionally, a plurality of first look-up tables and second look-up tables can be created that correspond to a particular digital broadcasting standard. The method can include determining which broadcast standard was used to encode the received signal and using the corresponding first look-up table and second look-up table corresponding to that standard.

In another example, a computing system for processing data is shown and described. The system can include a receiver and a central processing unit (CPU) in communication with the receiver. A broadcast signal is received by the receiver. The CPU executes an application that decodes the received broadcast signal. The application performs steps, such as, computing for each input of an error detection algorithm, prior to decoding the broadcast signal, a set of possible outcomes of the error detection algorithm and storing in a first look-up table, the computed set of possible outcomes of the error detection algorithm. The application also performs steps of computing for each input of an error correction algorithm, prior to decoding the broadcast signal, a set of possible error correction outcomes and storing in a second look-up table the computed set of possible error correction outcomes. In addition, the application performs steps such as detecting an error in a received broadcast signal using the first look-up table and when an error is detected, correcting the error using the second look-up table.

In another example, an article of manufacture is shown and described. The article includes a machine readable storage medium and executable program instructions embodied in the machine readable storage medium. When a programmable system executes the instructions, the programmable system executes functions to decode a received broadcast signal. The functions include computing for each input of an error detection algorithm, prior to decoding the broadcast signal, a set of possible outcomes of the error detection algorithm and storing in a first look-up table, the computed set of possible outcomes of the error detection algorithm. The functions also include computing for each input of an error correction algorithm, prior to decoding the broadcast signal, a set of possible error correction outcomes and storing in a second look-up table the computed set of possible error correction outcomes. In addition, the functions include detecting an error in a received broadcast signal using the first look-up table and when an error is detected, correcting the error using the second look-up table.

The apparatus, system, and method of the present disclosure can be used to decode many types of signals and data. For example, audio signals can be decoded. Also, video signals can be decoded. Of course, combined audio and video signals can be decoded. Thus, the apparatus, system, and method described herein can be used in television applications, audio applications, wireless communication applications (e.g., cellular telephones, wireless networking, and so on), networking applications, and other applications.

In one example, the disclosure features various form-factors that implement the decoding described herein. In one example, a decoder includes a processor (e.g., located in a set-top box) and associated software being executed by the software. In another example, the processor is located in cellular telephone and that the associated software is executed by the telephone. Of course, radios can include a processor that executes the associated software.

### BRIEF DESCRIPTION OF THE DRAWINGS

The drawing figures depict one or more implementations in accord with the present teachings, by way of example only, not by way of limitation. In the figures, like reference numerals refer to the same or similar elements.

FIG. 1 is a functional block diagram of an embodiment of a system for decoding a broadcast signal.

FIG. 2 is a flow chart depicting an embodiment of a method for decoding a broadcast signal.

FIG. 3 is a simplified functional block diagram of a computer that may be configured as a host or server.

FIG. 4 is a simplified functional block diagram of a personal computer or other work station or terminal device.

### DETAILED DESCRIPTION

In the following detailed description, numerous specific details are set forth by way of examples in order to provide a thorough understanding of the relevant teachings. However, it should be apparent to those skilled in the art that the present teachings may be practiced without such details. In other instances, well known methods, procedures, components, and/or circuitry have been described at a relatively high-level, without detail, in order to avoid unnecessarily obscuring aspects of the present teachings.

The various examples disclosed herein relate systems, method, and articles of manufacture for decoding a broadcast signal. In particular, aspects of the Reed-Solomon decoding algorithm are improved to thereby reduce the amount of processing time required to execute the Reed-Solomon decoding.

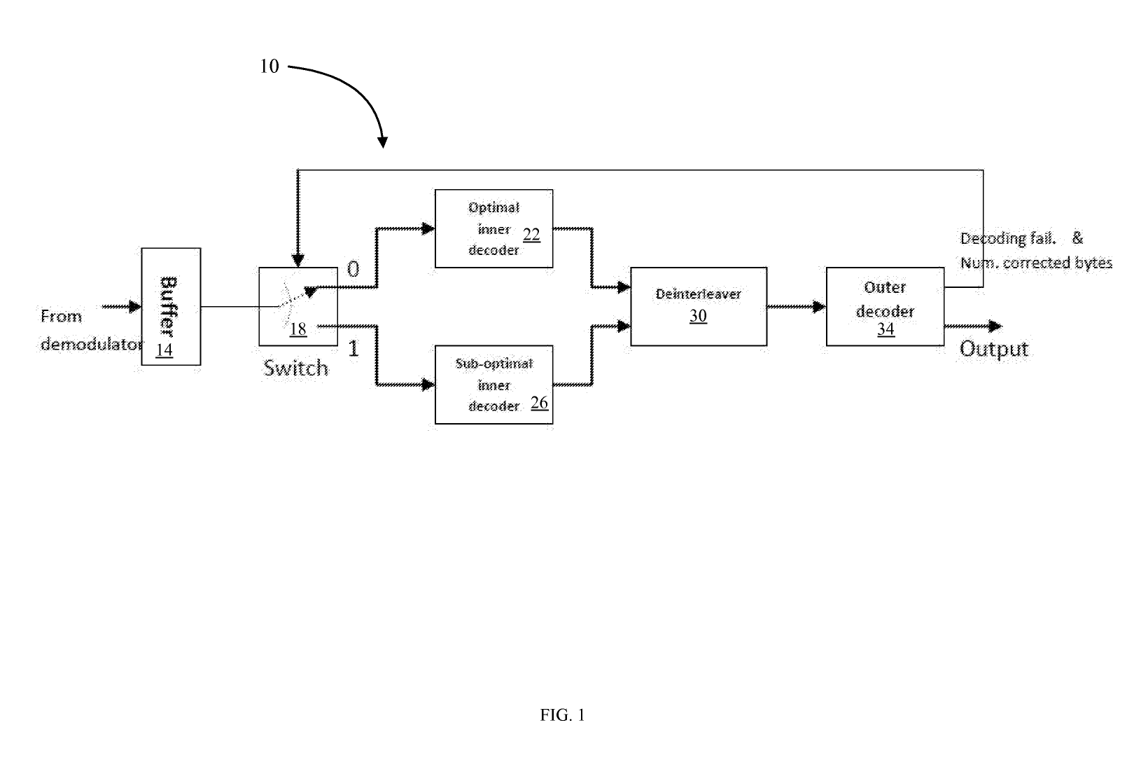

Reference now is made in detail to the examples illustrated in the accompanying drawings and discussed below. FIG. 1 depicts an embodiment of a system 10 for decoding a broadcast signal. The system 10 shows an example of performing serial concatenated decoding. It should be understood that other decoding schemes can also be used. The system 10 includes a buffer 14, a selector 18, an optimal inner decoder 22, a sub-optimal inner decoder 26, a deinterleaver 30, and an outer decoder 34.

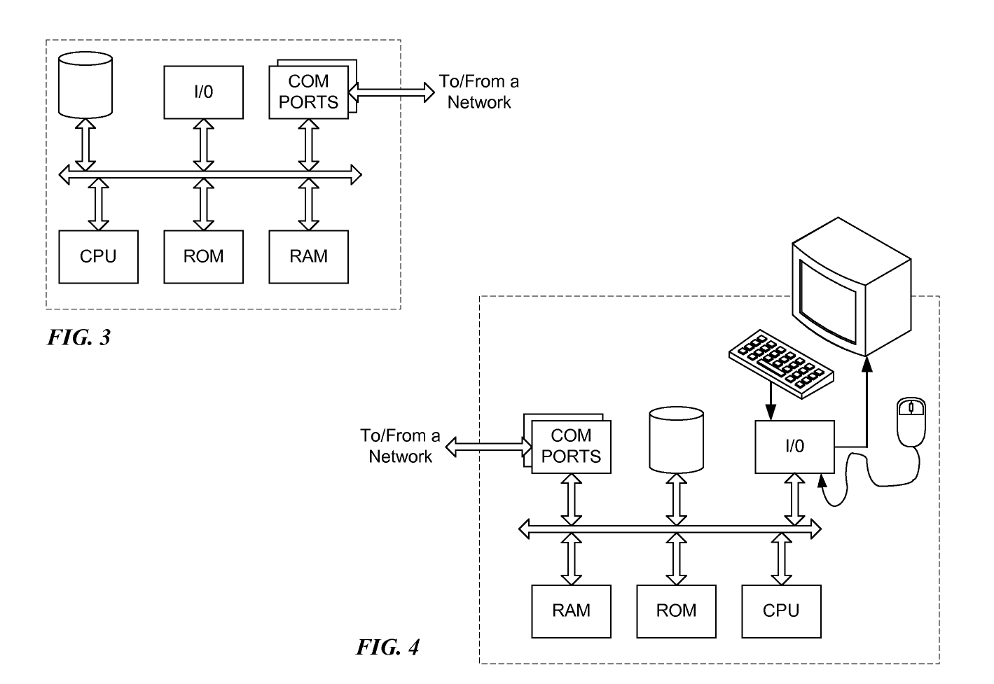

The buffer 14 is in communication with a demodulator (not shown) and the selector 18. The buffer 14 is in essence memory that stores blocks of data received from the demodulator. The data blocks represent the received signals of television broadcast in one example. The buffer 14 can be located within the memory of the computing device (e.g., personal computer) as shown in FIG. 3 and FIG. 4 that performs the decoding. The buffer 14 can be random access memory (RAM) and the like.

The storage size of the buffer 14 is selected, in one example, to be equal to the sum of the delays (expressed in terms of decoding blocks) for deinterleaver 30 and inner decoder 22, 26. Of course, the buffer 14 can be larger or smaller depending on the application. In one example, assume that the delay for the inner decoders 22, 26 is one data block. Storing the data blocks for a period of time allows for redecoding of certain data blocks as required. For example, if sub-optimal inner decoding is originally applied to a number of data blocks, it is possible that the output of the outer decoder will indicate an error. In such a case, all or some of the data blocks that were previously decoded using sub-optimal inner decoder 26 are retrieved from the buffer 14 and redecoded using the optimal inner decoder 22. Further details of redecoding are described below.

The selector 18 is in communication with the buffer 14 and both the optimal inner decoder 22 and the sub-optimal inner decoder 26. The selector 18 provides a mechanism to select either optimal inner decoding be applied to the data blocks received from the buffer 14 or sub-optimal inner decoding be applied to the data blocks received from the buffer 14. In essence, the selector 18 operates as a switch to connect one of the inner decoders 22, 26 with the buffer 14. The selector 18 can take many forms including a flag in a software routine or a physical electronic circuit (e.g., a transistor or diode). Although the selector 18 is shown as having two states position 0 or position 1, it should be understand that more states are possible depending on the number of inner decoders that are present.

The optimal inner decoder 22 is in communication with the selector 18 and the deinterleaver 30. The connection to the selector 18 can be established periodically. Said another way, the connection to the selector 18 can be temporarily applied and removed as required. Further details of this operation are discussed below. As used herein optimal refers to decoding that places a greater load on the processing when compared to the sub-optimal inner decoder 26. The use of “optimal” as a modifier in no way connotes an absolute measure of perfection. It is merely used to indicate a degree of separation between the inner decoders. For example, if three inner decoders were used they could conceptual be thought of a good inner decoder, a better inner decoder, and the best inner decoder for a specific application. In such a case, the “best inner decoder” can be considered the optimal inner decoder 22. In some applications, the optimal inner decoder 22 is implemented in hardware. In other applications, the optimal inner decoder 22 is implemented in software. Also, combinations of software and hardware can be used.

In one example, the optimal inner decoder 22 is a Viterbi decoder. The Viterbi decoder has a number of states (e.g., sixty-four). The optimal inner decoder 22 applies, in this example, a Viterbi decoding algorithm to the blocks of data received from the buffer 14.

In another example, the optimal inner decoder 22 can be Low Density Parity Check (LDPC) decoder that implements a greater number of decoding iterations when compared to the sub-optimal decoder 26. The optimal inner decoder 22 can implement any of a number decoding algorithms. Examples include, but are not limited to, the belief propagation algorithm, the message passing algorithm and the sum-product algorithm. LDPC codes are also referred to as Gallagher codes.

In yet another example, the optimal inner decoder 22 is a turbo code decoder. In a specific example, the optimal inner decoder 22 implements a log-MAP turbo decoding algorithm. Of course other known turbo code decoding algorithms can be used.

The sub-optimal inner decoder 26 is in communication with the selector 18 and the deinterleaver 30. The connection to the selector 18 can be established periodically. Said another way, the connection to the selector 18 can be temporarily applied and removed as required. Further details of this operation are discussed below. As used herein sub-optimal refers to decoding that reduces that load on the processing when compared to the optimal inner decoder 22. The use of “sub-optimal” as a modifier in no way connotes an absolute measure. In some applications, the sub-optimal inner decoder 26 is implemented in hardware. In other applications, the sub-optimal inner decoder 26 is implemented in software. Also, combinations of software and hardware can be used.

In some applications, the sub-optimal inner decoder 26 is selected as a compliment to the optimal inner decoder 22. For example, if a sixty-four state Viterbi decoder is the optimal decoder 22 the sub-optimal inner decoder 26 is a Viterbi decoder having fewer states (e.g., thirty-two). In another example, if the optimal inner decoder 22 is a thirty-two state Viterbi decoder the sub-optimal inner decoder 26 can have sixteen states. In another example, a LDPC decoding algorithm having a reduced number of decoding iterations when compared to the optimal decoder 26 is used. Also, the sub-optimal inner decoder 26 can execute a max-log-MAP turbo decoding algorithm when the optimal inner decoder 22 is implementing a log-MAP turbo code decoding algorithm. Of course, various combinations of the optimal inner decoders 22 and sub-optimal inner decoders 26 can be used provided the sub-optimal inner decoder reduces the processing load experienced by the processor performing the decoding.

The deinterleaver 30 is in communication with the optimal inner decoder 22 and the sub-optimal inner decoder 26. The deinterleaver 30 receives the inner-decoded data and randomizes the error pattern within the inner-decoded data. In some applications, the inner decoders 22, 26 operate on and produce as output bits of data. In such cases, the bits are converted to bytes prior to being operating on by the deinterleaver 30. In some examples, the deinterleaver 30 is a convolutional deinterleaver which has a delay of more than one decoding block.

The outer decoder 34 is in communication with the deinterleaver 30. The outer decoder 34 is assumed to be able to correct up to a specific number “B” of bytes. Said another way, the outer decoder 34 can accept an input having a maximum number of byte errors and successfully correct those errors. If the input to the outer decoder includes more than B errors, the output of the outer decoder 34 indicates a decoding failure. This indication is used, in some examples, to trigger a recoding with the optimal inner decoder 22 certain data blocks that were originally decoded using the sub-optimal inner decoder.

The outer decoder 34, in one example, is a Reed-Solomon (RS) decoder. The outer decoder 34 also indicates the number of corrections that it makes to the inner-decoded data. This measure of the number of corrections is used to determine whether optimal inner decoding or sub-optimal inner coding can be used by the system 10 without affecting the overall error performance of the system 10. Other decoders can be used as the outer decoder 34 provide it indicates, at a very high reliability, whether decoding failed or not. The output of the outer decoder 34 is decoded data.

One goal of the system 10 is to obtain substantially identical error performance within a device employing the optimal inner-decoder, however, when channel conditions allow the sub-optimal inner decoder is employed at a lower computational load. This can be achieved by monitoring the error statistics and accurately predicting in both modes of operations (i.e., optimal and sub-optimal) whether the other mode offers a lower computational load experienced by the processor. Fast switching between modes can respond to varying channel conditions. Thus, in either mode output error performance is substantially uncompromised.

In operation, the above-described system 10 provides serial concatenated decoding of data blocks. As shown, the system can provide two modes of operation. The first mode is referred to as sub-optimal mode. And the second mode is referred to as the optimal mode. In optimal mode, the selector 18 remains in position 0 thus establishing a communications path that includes the buffer 14, the optimal inner decoder 22, the deinterleaver 30, and the outer decoder 34.

In the sub-optimal mode, the selector 18 is usually in position 1; however, it switches to position 0 when re-decoding is activated as a result of an outer decoder 34 failure. When operating in sub-optimal mode, a communications path is established between the buffer 14, the sub-optimal inner decoder 26, the deinterleaver 30 and outer decoder 34. However, if recoding is needed the selector 18 temporarily transitions to position 0 to “switch in” the optimal inner decoder 22. This enables certain data blocks to be redecoded. After the certain data blocks are redecoded, the selector returns to position 1 and the sub-optimal inner decoder 26 is switched back into the processing path.

In some situations, the outer decoder 34 can account for a relatively large amount of time required to decode the received broadcast signal. This is due to the number of mathematical operations that needs to be performed. These operations are repeated for each input to the outer decoder 34. In some examples described below, instead of repeating these operations continually the results of the operations are pre-computed and stored in one or more look-up tables. The look-up tables practically contain a snapshot of each of the possible outputs of the mathematical operations using each of the possible input cases. Additionally, these look-up tables are organized in a manner that allows usage predetermination, so that explicit data pre-fetching techniques can be used to reduce memory stalls. Thus, computing and storing the results can decrease the amount or processing time and resources required to decode the received broadcast signal. The pre-computation can occur during the initialization of the decoding application.

As previously mentioned in some instances, the outer decoder 34 implements a Reed-Solomon decoding algorithm. The details of implementing a Reed-Solomon algorithm are understood by those of ordinary skill in the art and thus are not discussed in detail herein. At a high-level, a complete Reed-Solomon code consists of two parts: the data part and the parity part. For a Reed-Solomon code of n symbols, the first k symbols is the data part, which is the information to be protected against corruption, and the following (n-k) symbols is the parity part, which is calculated based on the data part. Such a Reed-Solomon code is referred to as an (n, k) Reed-Solomon code, or RS(n,k) code. The number of parity symbols is (n-k), usually an even number represented as 2 t. A Reed-Solomon code with 2 t parity symbols has the capability of correcting up to t error symbols.

A Reed-Solomon code is defined by a generator polynomial (e.g., g(X)=(X+a^{m0})(X+^{am0+1})(X+^{am0+2}) . . . (X+^{am0+2t-1})=g₀+g₁X+g₂X²+ . . . +_{g2-1}X^{2t-1}+X^{2t}), where a, an m-bit binary symbol, is the primitive element of the finite field GF(2^{m}), and m₀ is a pre-set number, usually 0 or 1.

To decode data, it can be thought of that the Reed-Solomon algorithm includes an error detection portion and an error correction portion. Each of these portions can be thought of as individual algorithms. In order to facilitate the understanding, it is helpful to use an example. Assume that the transmitted code vector is: t(X)=t₀+t₁X+t₂X²+ . . . +tₙ₋₁Xⁿ⁻¹. Also, assume that the received vector is: r(X)=r₀+r₁X+r₂X²+ . . . +rₙ₋₁Xⁿ⁻¹.

In order to detect errors, the outer decoders 34 calculates the 2t syndrome components. In the preceding example, the syndrome components are:

S₀=r(a⁰)=r₀+r₁+r₂+ . . . +ₘ₋₁;

S₁=r(a¹)=r₀+r₁(a)+r₂(a)²+ . . . +rₙ₋₁(a)ⁿ⁻¹

S₂=r(a²)=r₀+r₁(a²)+r₂(a²)²+ . . . +rₙ₋₁(a2)ⁿ⁻¹; . . .

S₂ₜ₋₁=r(a^{2t-1})=r₀+r₁(a^{2t-1})+r₂(a^{2t-1})²+ . . . +rₙ₋₁(a^{2t-1})ⁿ⁻¹.

The syndrome polynomial is: S(X)=S₀+S₁X+S₂X²+ . . . +S₂ₜ₋₁X^{2t-1}.

The outer decoder also determines the error location polynomial L(x) and the error evaluation polynomial W(x). The error location polynomial is L(x)=1+L₁X+L₂X²+ . . . +LₑX^{e}. The error evaluation polynomial is W(x)=W₀+W₁X+W₂X²+ . . . +Wₑ₋₁X^{e-1}, where e is the number of errors. The error location polynomial and the error evaluation polynomial are related to the syndrome polynomial through the equation L(X)S(X)=W(X) mod X^{2t}. In some examples, the outer decoder uses the iterative Berlekamp-Macey algorithm to solve for L(X) and W(X).

Using the above, the error location and the error value is obtained by the outer decoder 34. The error location can be obtained using Chien searching. Basically, X is substituted with aⁿ in L(X) for all possible n in a code to find the root of L(X). The inverse of the root of the error location polynomial is the error position.

If and once the location is found, the error value can be calculated using, for example, Forney's error evaluation algorithm. Once the error value is found, it is added to the corrupted symbol to correct the error.

As shown, this process is mathematically intensive. As mentioned, instead of performing these calculations for each input to the outer decoder 34, various portions of the outer decoder can be computed and stored as look-up tables. Thus the operational speed of the outer decoder is increased.

For example, for each input of the error detection algorithm the possible each possible output is computed at program initiation and stored in a first look-up table. The results can be stored as a three dimensional array by input, polynomial position, and outputs. Thus, instead of having to recalculate the output for each input, for a particular input the output value can be chosen from the look-up table. This increases the speed at which the outer decoder 34 can detect whether there are error present in the received data.

The same applies for the error correction portion of the algorithm. At program initiation, for each input to the error correction algorithm the respective outputs are calculated and stored. Again, the data can be stored in a three dimensional array. If an error is detected for a particular input, then the error correction look-up table is used to correct the error without having to perform the calculations. Instead, the corrected value is read from the look-up table.

The look-up tables can vary depending on what type of signal is being decoded. For example, if a specific digital television standard is being decoded a certain error detection and error correction look-up table is chosen. In some embodiments, the error correction and error detection look-up tables for each of the standards supported by the application are calculated upon program initiation. Of course, a subset of those look-up tables can also be calculated.

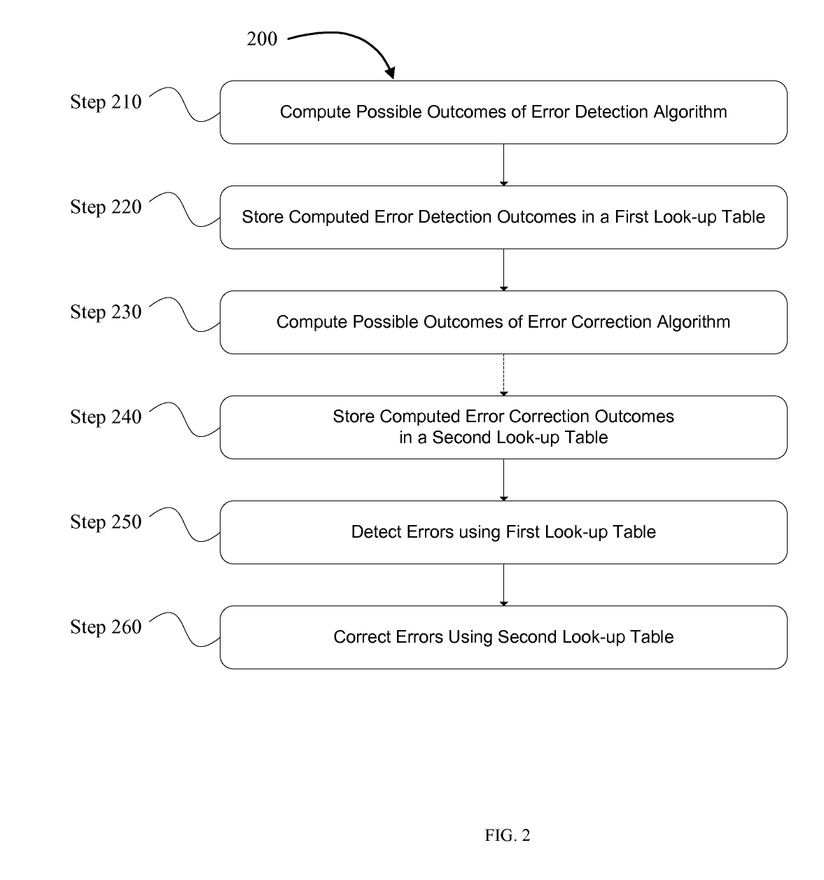

With reference to FIG. 2, a method 200 of decoding a broadcast signal is shown and described. The method includes computing (step 210) the possible outcomes of an error detection algorithm, storing (step 220) the computed possible error detection outcomes in a first look-up table. The method 200 also includes computing (step 230) the possible outcomes of an error correction algorithm and storing (step 240) the computed error correction outputs in a second look-up table. The method 200 also includes detecting (step 250) an error using the first look-up table and correcting (step 270) the detected error using the second look-up table.

As discussed above, the computation (steps 210 and 230) of the error detection look-up table and the error correction look-up table can be calculated at the initiation of the application used to decode the received broadcast signals. Also, a respective first look-up table and respective second look-up table can be calculate for each type of received signal supported by the application. Examples of support signals include, but are not limited to, DVB-T, T-DMB, DMB-T/H, and HD Radio and others.

During execution of the application, errors can be detected in the received signal using only the first look-up table. It may be needed to perform some mathematical operations in conjunction with the use of the first look-up table in some applications. In such cases, it is still beneficial to use look-up tables to perform aspects of the decoding. The same applies for the use of the error correction look-up table. That is, in some examples only the second look-up table is used. In other examples, some computations are also used.

In testing the above approach, it is noticed that the performance gain was marked. For an error free signal, the proposed approach proved to be about ten times faster than the existing mathematical approach, and about four times faster than the approach used by an instruction set targeted Reed-Solomon implementation. For the worst case scenario (e.g., the maximum correctable errors), the proposed approach proved to be about five times faster than the existing mathematical approach, and about two times faster than the targeted instruction set approach.

The proposed approach is portable and was already tested on different other applications, and changing from any possible configuration (needed by different applications) can be done in a very short time (order of minutes). And because it is a memory centric approach, not mathematical centric approach, the proposed solution can be freely ported on any PC CPU configurations, without the risk of encountering compatibility problems (e.g. related to the instruction set).

FIGS. 3 and 4 provide functional block diagram illustrations of general purpose computer hardware platforms. FIG. 3 illustrates a network or host computer platform, as may typically be used to implement a server. FIG. 4 depicts a computer with user interface elements, as may be used to implement a personal computer (PC) or other type of work station or terminal device, although the computer of FIG. 4 may also act as a server if appropriately programmed. It is believed that those skilled in the art are familiar with the structure, programming and general operation of such computer equipment and as a result the drawings should be self-explanatory.

The hardware elements, operating systems and programming languages of such computers are conventional in nature, and it is presumed that those skilled in the art are adequately familiar therewith. Of course, the server functions may be implemented in a distributed fashion on a number of similar platforms, to distribute the processing load.

Hence, aspects of the methods of decoding a broadcast signal outlined above may be embodied in programming. Program aspects of the technology may be thought of as “products” or “articles of manufacture” typically in the form of executable code and/or associated data that is carried on or embodied in a type of machine readable medium. “Storage” type media include any or all of the memory of the computers, processors or the like, or associated modules thereof, such as various semiconductor memories, tape drives, disk drives and the like, which may provide storage at any time for the software programming. All or portions of the software may at times be communicated through the Internet or various other telecommunication networks. Such communications, for example, may enable loading of the software from one computer or processor into another, for example, from a management server or host computer of the network operator or carrier into the computer platform of the data aggregator and/or the computer platform(s) that serve as the customer communication system. Thus, another type of media that may bear the software elements includes optical, electrical and electromagnetic waves, such as used across physical interfaces between local devices, through wired and optical landline networks and over various air-links. The physical elements that carry such waves, such as wired or wireless links, optical links or the like, also may be considered as media bearing the software. As used herein, unless restricted to tangible “storage” media, terms such as computer or machine “readable medium” refer to any medium that participates in providing instructions to a processor for execution.

Hence, a machine readable medium may take many forms, including but not limited to, a tangible storage medium, a carrier wave medium or physical transmission medium. Non-volatile storage media include, for example, optical or magnetic disks, such as any of the storage devices in any computer(s) or the like, such as may be used to implement the data aggregator, the customer communication system, etc. shown in the drawings. Volatile storage media include dynamic memory, such as main memory of such a computer platform. Tangible transmission media include coaxial cables; copper wire and fiber optics, including the wires that comprise a bus within a computer system. Carrier-wave transmission media can take the form of electric or electromagnetic signals, or acoustic or light waves such as those generated during radio frequency (RF) and infrared (IR) data communications. Common forms of computer-readable media therefore include for example: a floppy disk, a flexible disk, hard disk, magnetic tape, any other magnetic medium, a CD-ROM, DVD or DVD-ROM, any other optical medium, punch cards paper tape, any other physical storage medium with patterns of holes, a RAM, a PROM and EPROM, a FLASH-EPROM, any other memory chip or cartridge, a carrier wave transporting data or instructions, cables or links transporting such a carrier wave, or any other medium from which a computer can read programming code and/or data. Many of these forms of computer readable media may be involved in carrying one or more sequences of one or more instructions to a processor for execution.

Those skilled in the art will recognize that the present teachings are amenable to a variety of modifications and/or enhancements. For example, although the above examples related to decoding in a television broadcasting environment the benefits described herein are equally applicable to radio broadcasts, cellular communications, and other communications systems where serial concatenated decoding is used. Also, although two inner decoders are shown, more than two can be used. Thus, varying degrees of processor load reductions can be achieved.

While the foregoing has described what are considered to be the best mode and/or other examples, it is understood that various modifications may be made therein and that the subject matter disclosed herein may be implemented in various forms and examples, and that the teachings may be applied in numerous applications, only some of which have been described herein. It is intended by the following claims to claim any and all applications, modifications and variations that fall within the true scope of the present teachings.

What is claimed is:

1. A method of decoding a received broadcast signal, comprising the steps of:
(a) computing for each input of an error detection algorithm, prior to decoding the broadcast signal, a set of possible outcomes of the error detection algorithm;
(b) storing in a first look-up table, the computed set of possible outcomes of the error detection algorithm;
(c) computing for each input of an error correction algorithm, prior to decoding the broadcast signal, a set of possible error correction outcomes;
(d) storing in a second look-up table the computed set of possible error correction outcomes;
(e) detecting an error in a received broadcast signal using the first look-up table; and
(f) when an error is detected, correcting the error using the second look-up table.

2. The method of claim 1 wherein the detecting occurs using only the first look-up table.

3. The method of claim 1 wherein the correcting occurs using only the second look-up table.

4. The method of claim 1 wherein the broadcast signal is a digital television broadcast signal.

5. The method of claim 1 wherein the error detection algorithm and error correction algorithm comprise a Reed-Solomon algorithm.

6. The method of claim 1 wherein computing for each input of an error correction algorithm comprises performing a Chien search.

7. The method of claim 1 wherein storing the first look-up table comprises storing the first look-up table as a three-dimensional array.

8. The method of claim 1 wherein storing the second look-up table comprises storing the second look-up table as a three-dimensional array.

9. The method of claim 1 further comprising repeating steps (a), (b), (c), and (d), for each one of a plurality of digital broadcast television standards; determining which digital broadcast standard is received; and wherein steps (e) and (f) are based on the respective first look-up table and second look-up table for the determined digital broadcast standard.

10. A computing system for processing data, the system comprising:
a receiver for receiving a broadcast signal; and
a central processing unit (CPU) in communication with the receiver, the CPU executing an application that decodes the broadcast signal, the application performing the steps of:
(a) computing for each input of an error detection algorithm, prior to decoding the broadcast signal, a set of possible outcomes of the error detection algorithm;
(b) storing in a first look-up table, the computed set of possible outcomes of the error detection algorithm;
(c) computing for each input of an error correction algorithm, prior to decoding the broadcast signal, a set of possible error correction outcomes;
(d) storing in a second look-up table the computed set of possible error correction outcomes;
(e) detecting an error in a received broadcast signal using the first look-up table; and
(f) when an error is detected, correcting the error using the second look-up table.

11. The system of claim 10 wherein the detecting occurs using only the first look-up table.

12. The system of claim 10 wherein the correcting occurs using only the second look-up table.

13. The system of claim 10 wherein the broadcast signal is a digital television broadcast signal.

14. The system of claim 10 wherein the error detection algorithm and error correction algorithm comprise a Reed-Solomon algorithm.

15. The system of claim 10 wherein computing for each input of an error correction algorithm comprises performing a Chien search.

16. The system of claim 10 wherein storing the first look-up table comprises storing the first look-up table as a three-dimensional array.

17. The system of claim 10 wherein storing the second look-up table comprises storing the second look-up table as a three-dimensional array.

18. The system of claim 10 further comprising repeating steps (a), (b), (c), and (d), for each one of a plurality of digital broadcast television standards; determining which digital broadcast standard is received; and wherein steps (e) and (f) are based on the respective first look-up table and second look-up table for the determined digital broadcast standard.

19. An article of manufacture comprising:
a machine readable storage medium; and
executable program instructions embodied in the machine readable storage medium that when executed by a programmable system causes the system to perform functions that decode broadcast signals, the functions comprising:
(a) computing for each input of an error detection algorithm, prior to decoding the broadcast signal, a set of possible outcomes of the error detection algorithm;
(b) storing in a first look-up table, the computed set of possible outcomes of the error detection algorithm;
(c) computing for each input of an error correction algorithm, prior to decoding the broadcast signal, a set of possible error correction outcomes;
(d) storing in a second look-up table the computed set of possible error correction outcomes;
(e) detecting an error in a received broadcast signal using the first look-up table; and
(f) when an error is detected, correcting the error using the second look-up table.

20. The article of manufacture of claim 19 wherein the detecting occurs using only the first look-up table.

21. The article of manufacture of claim 19 wherein the correcting occurs using only the second look-up table.

22. The article of manufacture of claim 19 wherein the broadcast signal is a digital television broadcast signal.

23. The article of manufacture of claim 19 wherein the error detection algorithm and error correction algorithm comprise a Reed-Solomon algorithm.

24. The article of manufacture of claim 19 wherein computing for each input of an error correction algorithm comprises performing a Chien search.

25. The article of manufacture of claim 19 wherein storing the first look-up table comprises storing the first look-up table as a three-dimensional array.

26. The article of manufacture of claim 19 wherein storing the second look-up table comprises storing the second look-up table as a three-dimensional array.

27. The article of manufacture of claim 19 wherein the functions further comprise repeating steps (a), (b), (c), and (d), for each one of a plurality of digital broadcast television standards; determining which digital broadcast standard is received; and wherein steps (e) and (f) are based on the respective first look-up table and second look-up table for the determined digital broadcast standard.
